(19) United States
(12) Patent Application Publication
(10) Pub. No.: US 2023/0070486 A1
(43) Pub. Date: Mar. 9, 2023

(54) TECHNOLOGIES FOR MAGNETIC-TUNNEL-JUNCTION-BASED RANDOM NUMBER GENERATION

(71) Applicant: Intel Corporation, Santa Clara, CA (US)

(72) Inventors: Punyashloka Debashis, Hillsboro, OR (US); Ian Alexander Young, Olympia, WA (US); Dmitri Evgenievich Nikonov, Beaverton, OR (US); Marko Radosavljevic, Portland, OR (US); Hai Li, Portland, OR (US)

(73) Assignee: Intel Corporation, Santa Clara, CA (US)

(21) Appl. No.: 17/467,124

(22) Filed: Sep. 3, 2021

(51) Int. Cl. G11C 11/16; G06F 7/58; G06F 17/16

(52) U.S. Cl. CPC G11C 11/1693; G11C 11/1673; G11C 11/1675; G11C 11/161; G06F 7/588; G06F 17/16

(57) ABSTRACT

Technologies for non-uniform random number generation are disclosed. In one embodiment, the distribution of resistance of a magnetic tunnel junction (MTJ) can be controlled by applying a mechanical strain with a piezoelectric layer and by applying a spin torque by a spin-orbit torque layer. The distribution of resistance can be approximately a Gaussian distribution. In another embodiment, an array of N probabilistic bits (p-bits) has a bias and feedback matrix that result in the array of p-bits outputting an N-bit random number with a non-uniform distribution, such as a Gaussian distribution.

### BACKGROUND

Random numbers are a resource used in many applications, such as machine learning, Bayesian inference, optimization algorithms, etc. Pseudo-random numbers can be generated using deterministic logic gates using techniques such as linear feedback shift registers. Such random number generators typically require a large footprint, produce a uniform number distribution, and are not truly random.

### BRIEF DESCRIPTION OF THE DRAWINGS

FIG. 1 is an isometric view of a system with a magnetic tunnel junction.

FIG. 2 is a top-down view of the system of FIG. 1.

FIG. 3 is a cross-sectional side view of the system of FIG. 1.

FIG. 4A shows a distribution of one angle of the magnetization of one embodiment of the magnetic tunnel junction of FIG. 1.

FIG. 4B shows a simulation of resistance over time of one embodiment of the magnetic tunnel junction of FIG. 1.

FIG. 4C shows a distribution of resistance of one embodiment of the magnetic tunnel junction of FIG. 1.

FIG. 5A shows a distribution of one angle of the magnetization of one embodiment of the magnetic tunnel junction of FIG. 1.

FIG. 5B shows a simulation of resistance over time of one embodiment of the magnetic tunnel junction of FIG. 1.

FIG. 5C shows a distribution of resistance of one embodiment of the magnetic tunnel junction of FIG. 1.

FIG. 6A shows a distribution of one angle of the magnetization of one embodiment of the magnetic tunnel junction of FIG. 1.

FIG. 6B shows a measurement of resistance over time of one embodiment of the magnetic tunnel junction of FIG. 1.

FIG. 7 is a simplified flow diagram of at least one embodiment of a method for creating the system of FIG. 1.

FIG. 8 is a simplified block diagram of one embodiment of a system for random number generation.

FIG. 9A shows a simulation of a distribution of number generation of one embodiment of the system of FIG. 8.

FIG. 9B shows a simulation of a distribution of number generation of one embodiment of the system of FIG. 8.

FIG. 9C shows a simulation of a distribution of number generation of one embodiment of the system of FIG. 8.

FIG. 9D shows a simulation of a distribution of number generation of one embodiment of the system of FIG. 8.

FIG. 10 is an isometric view of a system with a magnetic tunnel junction.

FIG. 11 is a top-down view of the system of FIG. 10.

FIG. 12 is a cross-sectional side view of the system of FIG. 10.

FIG. 13 is one embodiment of a probabilistic bit of the system of FIG. 8.

FIG. 14 is a top view of a wafer and dies that may be included in a microelectronic assembly, in accordance with any of the embodiments disclosed herein.

FIG. 15 is a cross-sectional side view of an integrated circuit device that may be included in a microelectronic assembly, in accordance with any of the embodiments disclosed herein.

FIGS. 16A-16D are perspective views of example planar, gate-all-around, and stacked gate-all-around transistors.

FIG. 17 is a cross-sectional side view of an integrated circuit device assembly that may include a microelectronic assembly, in accordance with any of the embodiments disclosed herein.

FIG. 18 is a block diagram of an example electrical device that may include a microelectronic assembly, in accordance with any of the embodiments disclosed herein.

### DETAILED DESCRIPTION

In various embodiments disclosed herein, random fluctuations of magnetization of a magnetic tunnel junction (MTJ) can be used to generate true random number generation with a non-uniform distribution. In one embodiment, the distribution of the resistance of an MTJ can be controlled. In particular, the standard deviation of the distribution can be controlled by tuning the mechanical strain applied to the MTJ by a piezoelectric layer, and the mean of the distribution can be controlled using spin-orbit torque. In another embodiment, an array of probabilistic bits based on MTJs are interconnected to generate a random digital output with a Gaussian probability distribution.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate, and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

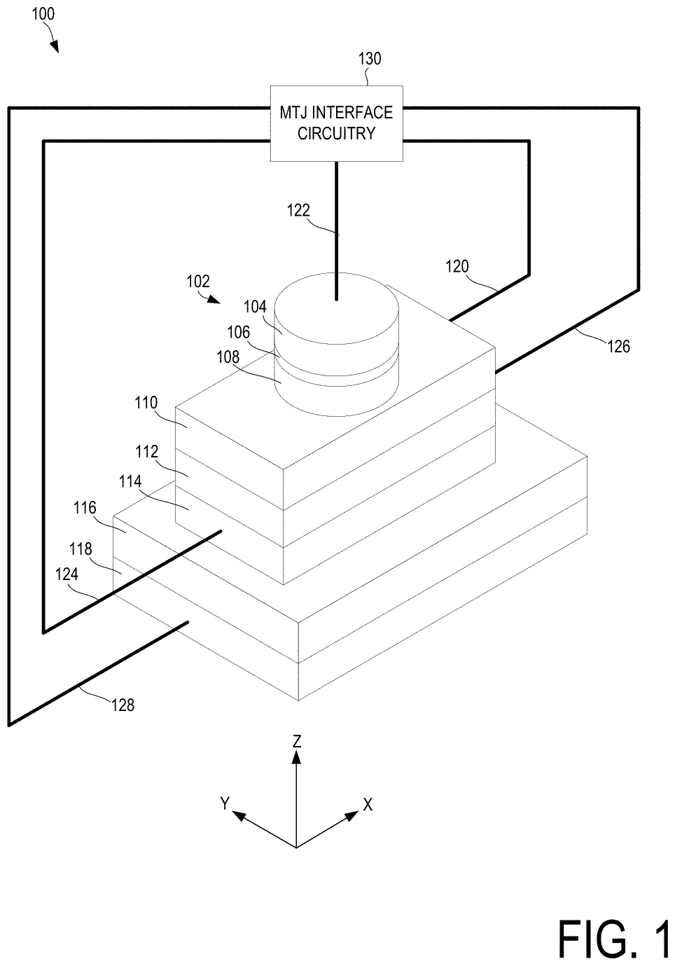

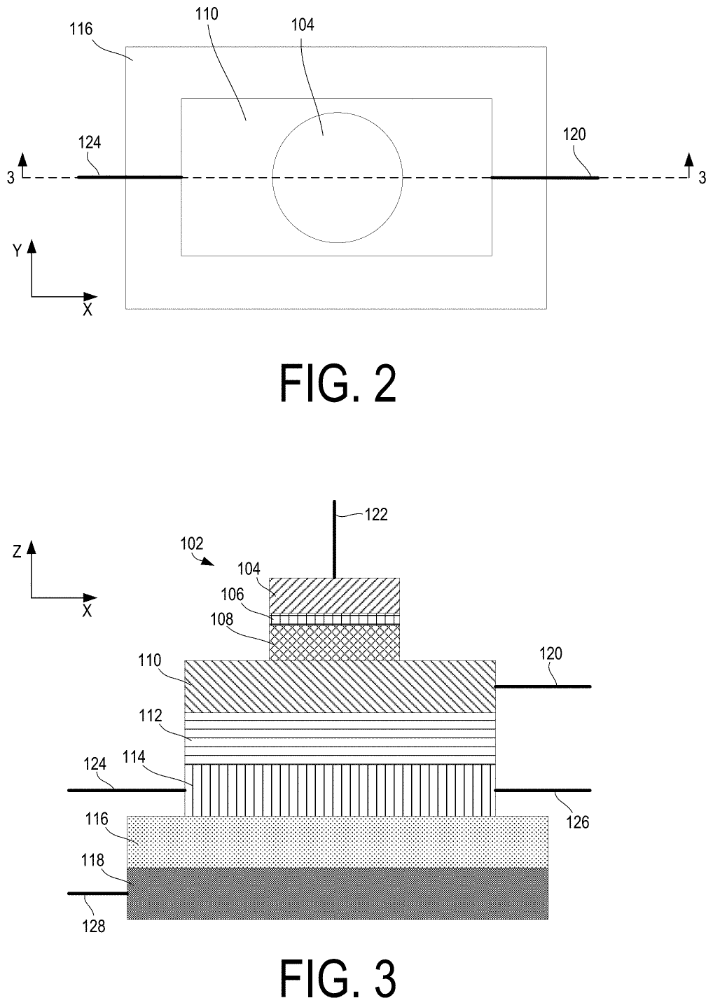

Referring now to FIGS. 1-3, in one embodiment, a system 100 includes a magnetic tunnel junction (MTJ) 102 with a reference ferromagnetic layer 104, a dielectric layer 106, and a free ferromagnetic layer 108. FIG. 2 shows a top-down view of the system 100, and FIG. 3 shows a cross-sectional view of the system 100 taken along the dashed line in FIG. 2. The MTJ 102 is on top of a normal (i.e., non-spin-orbit torque) metal layer 110, an isolation layer 112, and spin-orbit torque (SOT) layer 114. The spin-orbit torque layer 114 is on top of piezoelectric layer 116 and a normal metal layer 118. A first MTJ electrode 120 and second MTJ electrode 122 are connected to the MTJ 102 and can be used to probe the resistance of the MTJ 102. An electrode 124 can be used to supply current to the spin-orbit torque layer 114 by applying a voltage relative to a ground electrode 126. An electrode 128 connected to the normal metal layer 118 can be used to apply a voltage across the piezoelectric layer 116. MTJ interface circuitry 130 is able to probe the resistance of the MTJ 102 using the MTJ electrodes 120, 122. In some embodiments, the system 100 may include a temperature sensor and/or temperature controller to sense and/or control the temperature of the MTJ 102.

In use, the reference ferromagnetic layer 104 is polarized in the plane of the layer 104, and the free ferromagnetic layer 108 acts as a free nanomagnet whose direction of magnetization can fluctuate due to thermal fluctuations. When the orientation of the free nanomagnet is aligned parallel with the reference ferromagnetic layer 104, the resistance of the MJT 102 is low, and when the orientation of the free nanomagnet is aligned antiparallel with the reference ferromagnetic layer 104, the resistance of the MJT 102 is high. The resistance of the MTJ 102 is determined by the direction of the magnetization of the free ferromagnetic layer 108 according to the equation:

R_{MTJ}=R₀/(1+P² cos φ sin θ), (1)

where R_{MTJ} is the resistance of the MTJ 102, R₀ is the average resistance of the MTJ 102, P is the polarization of the MTJ 102, and θ and φ are the polar and azimuthal angle, respectively, of the magnetization of the free ferromagnetic layer 108 with respect to the normal vector of the plane of the free ferromagnetic layer 108. The magnetization direction of the free ferromagnetic layer 108 follows the Boltzmann distribution according to the equation

$$p ( θ , φ ) = \frac{1}{Z} {e}^{- E ( θ , φ ) / {k}_{B} T} , \qquad ( 2 )$$

where p(θ,φ) is the probability of the magnetization being along the direction (θ, φ), E(θ,φ) is the energy for the direction (θ, φ), k_{B} is the Boltzmann constant, T is the temperature, and Z is the partition function to normalize the probability function.

The energy function E depends on the interface anisotropy energy density K_{S} of the free ferromagnetic layer 108, which can be controlled by application of a mechanical strain by the piezoelectric layer 116, which slightly deforms upon application of a voltage across it. The piezoelectric layer 116 is mechanically coupled to the free ferromagnetic layer 108 (i.e., the piezoelectric layer 116 is in physical contact with the free ferromagnetic layer 108, either directly or with one or more intervening layers). The strain from the piezoelectric layer 116 can propagate through thin layers (such as layers 114, 112, and 110) to the free ferromagnetic layer 108. The change in K_{S} affects the preference of the magnetization of the free ferromagnetic layer 108 to be in the plane of the free ferromagnetic layer 108 rather than perpendicular to the plane (i.e., the change in K_{S} changes the distribution of the polar angle θ in Eq. 1 above). If the polar angle θ is small, then the distribution of R_{MTJ} is relatively narrow, and, if the polar angle θ is large, then the distribution of R_{MTJ} is relatively large. As such, application of a voltage across the piezoelectric layer 116 can control the standard deviation of the distribution of the resistance of the MTJ 102.

When current is passed through the SOT layer 114, the spin Hall effect results in an increased density of one spin state at the top of the SOT layer 114. The isolation layer 112 and normal layer 110 are designed to allow a net spin current to propagate from the SOT layer 114 to the free ferromagnetic layer 108. When a charge current is passed along the X-direction, a spin current flows along the Z-direction, with a spin polarization pointing in the ±Y direction, depending on the direction of the charge current flow. The spin polarization results in a spin torque on the free ferromagnetic layer 108, providing a bias that can affect the in-plane orientation of the magnetization of the free ferromagnetic layer (i.e., the change in current changes the distribution of the azimuthal angle φ in Eq. 1 above). A bias in the azimuthal angle φ in Eq. 1 can shift the mean value of the resistance R_{MTJ}. As a result, controlling the field across the piezoelectric layer 118 and the current through SOT layer 114 allows for control of both the standard deviation and the mean of the resistance R_{MTJ}.

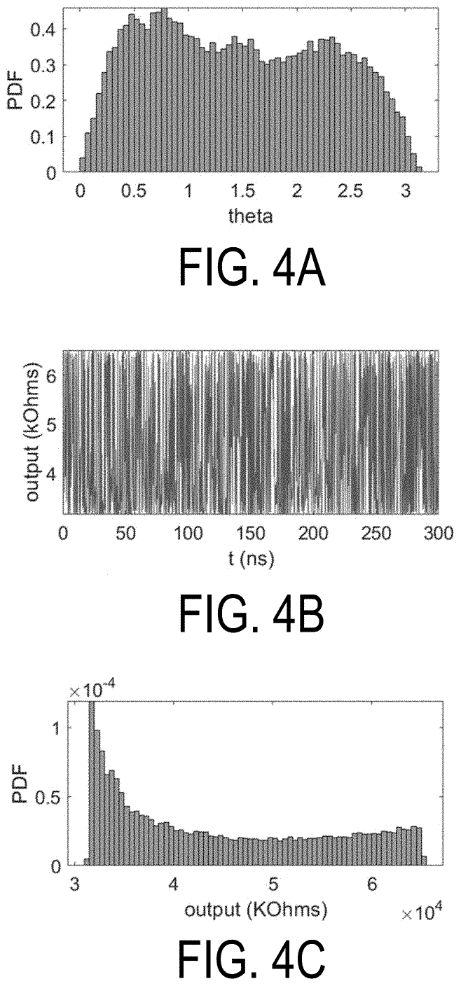

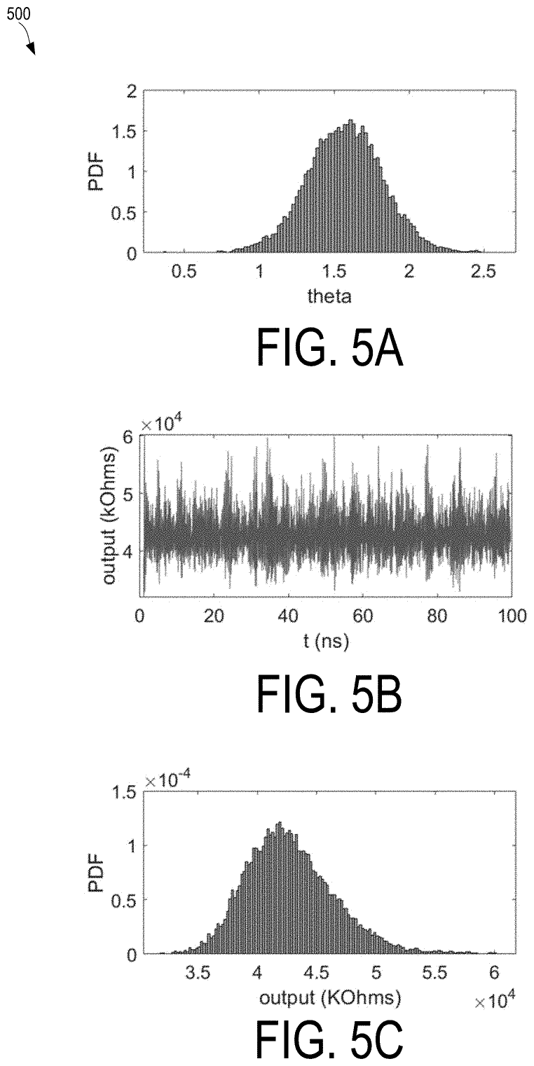

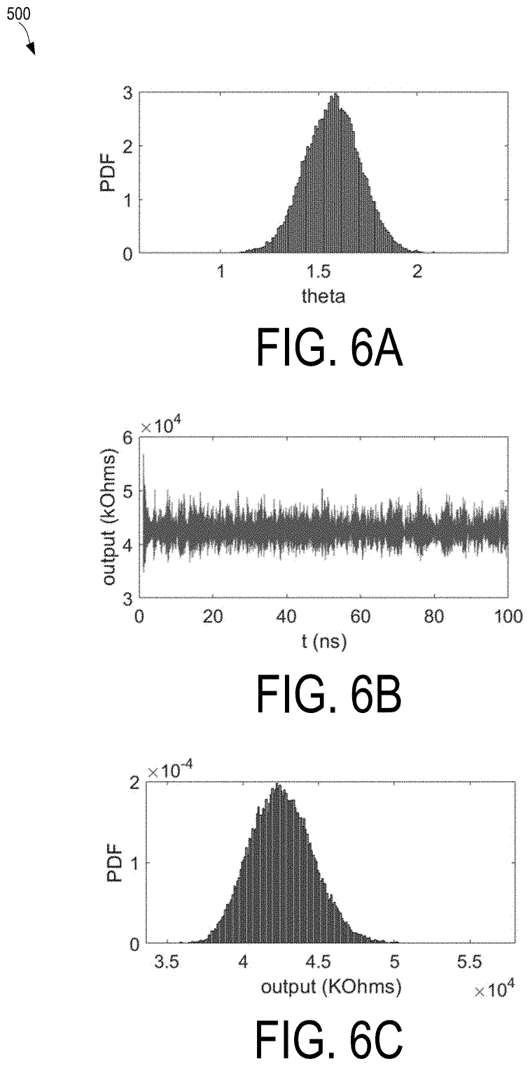

For example, in one embodiment, FIGS. 4A-4C show simulation results of the Landau-Lifshitz-Gilbert (LLG) equation in the presence of noise where K_{S} is set to 1.2 by the piezoelectric layer 118. FIG. 4A shows the relatively wide distribution of the probability density function (PDF) of B. FIG. 4B shows the fluctuation in the resistance of the MTJ 102 as a function of time. FIG. 4C shows the distribution of the resistance measurement. FIGS. 5A-5C and FIGS. 6A-6C show similar simulation results with K_{S} set to 1.3 and 1.4, respectively. FIGS. 4C, 5C, and 6C show that the standard deviation of the resistance is dependent on the interface anisotropy energy density K_{S}, which is controllable based on the voltage across the piezoelectric layer 118. In particular, FIGS. 5C and 6C have approximately a Gaussian distribution, while FIG. 4C has a distribution that is flatter and closer to a uniform distribution.

In the illustrative embodiment, the resistance of the MTJ 102 randomly changes on a nanosecond timescale, and the distribution of the resistance of the MTJ 102 also responds to a change in parameters (e.g., to a change in the voltage across the piezoelectric layer 116 or the current in the SOT layer 114). For example, if the piezoelectric layer 116 has a change in voltage, the distribution of the resistance of the MTJ 102 may change in, e.g., 1-10 nanoseconds. In use, the variation of resistance of the MTJ 102 may be used as a random parameter. For example, the variation of resistance of the MTJ 102 may be used directly as an analog random voltage (by applying a fixed current to the MTJ 102) or an analog random current (by applying a fixed voltage to the MTJ 102). Additionally or alternatively, in some embodiments, the resistance of the MTJ 102 may be measured using an analog-to-digital converter, allowing the MTJ 102 to be used as a digital random number generator with a variable, controllable standard deviation and mean. The MTJ 102 may be used as a random parameter in any suitable application, such as machine learning, Bayesian inference, optimization algorithms, Monte Carlo simulations, etc. In some embodiments, the MTJ 102 may be used as a Gaussian random parameter. As the randomness of the resistance of the MTJ 102 is thermally-driven and not deterministic, the MTJ 102 can act as a true random number generator (as opposed to a deterministic pseudo-random number generator).

The MTJ 102 may be any suitable MTJ with any suitable materials. For example, the reference ferromagnetic layer 104 and/or the free ferromagnetic layer 108 may be any suitable ferromagnetic material, such as Fe, FeCo, CoFeB, etc. The dielectric layer 106 may be any suitable dielectric, such as MgO.

The normal metal layers 110, 128 may be any suitable material, such as copper, aluminum, etc. The isolation layer 112 may be any suitable isolation layer, such as NiO.

The SOT layer 114 may be any suitable SOT material, such as a heavy metal (e.g., Pt, Ta, W, Hf, Pd), an antiferromagnet (e.g., FeMn, PdMn, IrMnX, PtMn), topological insulators (e.g., Bi₂Se, BiₓSe₁₋ₓ, BiTe, SbTe, BiₓSb₁₋ₓTe, Bi_{0.9}Sb_{0.1}, SnTe), transition metal dichalcogenides (e.g., MoS₂, WSe₂, WTe₂, PtTe₂, MoTe₂, NbSe₂), etc. The piezoelectric layer 116 may be any suitable piezoelectric material, such as PbTiO₃, AlPO₄, KNbO₃, Ba₂NaNb₅O₅, PbKNbO₁₅, BiFeO₃, Bi₄TiO₁₂, NaNbO₃, KNaNbO₃, BaTiO₃, PbZrTiO₃, PMN-PT (Pb(Mg_{1/3}Nb_{2/3})O₃—PbTiO₃), LiNbO₃, Na_{0.5}Bi_{4.5}Ti₄O₁₅, PbTiO₃, PbNb₂O₆, LiTaO₃, AlN, GaN, InN, ZnO, polyvinylidene fluoride, polyamides, parylene-C, polyvinylidene chloride, etc.

Each electrode 120, 122, 124, 126, 128 may be any suitable material, such as copper, aluminum, or other conductive material.

The MTJ interface circuitry 130 is configured to interface with the MTJ 102 and other components of the system 100, such as electrodes 126 that acts as a ground, electrode 128 that controls the electric field across the piezoelectric layer 116, electrode 124 that provides current into or out of the SOT layer 114, and electrodes 120, 122 that can probe the resistance of the MTJ 102. The MTJ interface circuitry 130 may be integrated with the MTJ 102 and other components of the system 100 on the same chip, on a multi-chip package, on a system-on-a-chip, on a separate chip or package, etc. The MTJ interface circuitry 130 may include voltage and/or current sources, analog-to-digital converters (which may be used to convert the analog resistance of the MTJ 102 to a digital value), digital-to-analog converters, etc. The MTJ interface circuitry 130 and/or any other components of the system 100 may be integrated with or otherwise form part of a processor, an application-specific integrated circuit (ASIC), a field-programmable gate array (FPGA), a graphics processing unit (GPU), etc.

It should be appreciated that the configuration shown in FIG. 1 is merely one possible arrangement of the various components. It should be appreciated that the various layers may be arranged in a different order or arranged in a different configuration.

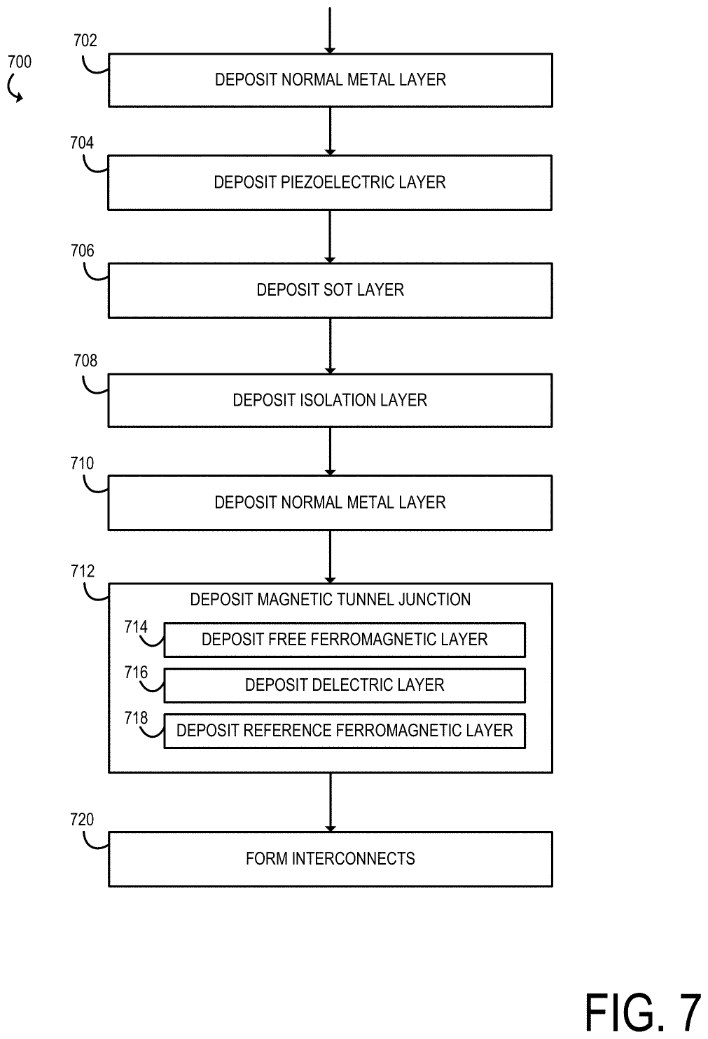

Referring now to FIG. 7, in one embodiment, a flowchart for a method 700 for creating the system 100 with an MTJ 102 is shown. The method 700 may be executed by a technician and/or by one or more automated machines. In some embodiments, one or more machines may be programmed to do some or all of the steps of the method 700. Such a machine may include, e.g., a memory, a processor, data storage, etc. The memory and/or data storage may store instructions that, when executed by the machine, causes the machine to perform some or all of the steps of the method 700. The method 700 may use any suitable set of techniques that are used in semiconductor processing, such as chemical vapor deposition, atomic layer deposition, physical layer deposition, molecular beam epitaxy, layer transfer, photolithography, ion implantation, dry etching, wet etching, thermal treatments, flip chip, layer transfer, magnetron sputter deposition, pulsed laser deposition, etc. It should be appreciated that the method 700 is merely one embodiment of a method to create the system 100, and other methods may be used to create the system 100.

The method 700 begins in block 702, in which the first normal metal layer 118 is deposited. The normal metal layer 118 may be deposited on a substrate, such as silicon, silicon dioxide, etc. The normal metal layer 118 (and other layers described herein) may be deposited in any suitable manner, such as atomic layer deposition, chemical vapor deposition, atomic layer deposition, molecular beam epitaxy, etc. Depositing a layer may include use photolithography, etching, polishing, layer transfer, etc. that is not described in detail for each layer.

In block 704, the piezoelectric layer 116 is deposited on the normal metal layer 118, followed by deposition of the SOT layer 114 in block 706 and the isolation layer 112 in block 708. The normal metal layer 110 is then deposited on the isolation layer 112 in block 710. The magnetic tunnel junction 102 is deposited on the normal metal layer 110. The magnetic tunnel junction 102 may be deposited by depositing a free ferromagnetic layer in block 714, depositing a dielectric layer in block 716, and depositing a reference ferromagnetic layer in block 718. The free ferromagnetic layer and the reference ferromagnetic layer may include multiple layers of magnetic and non-magnetic metals.

In block 720, interconnects are formed to and from various components of the system 100, such as electrodes 120, 122, 124, 126, and 128. In some embodiments, some or all of the electrodes 120, 122, 124, 126, and 128 may be formed as part of or in between steps 702-718 described above.

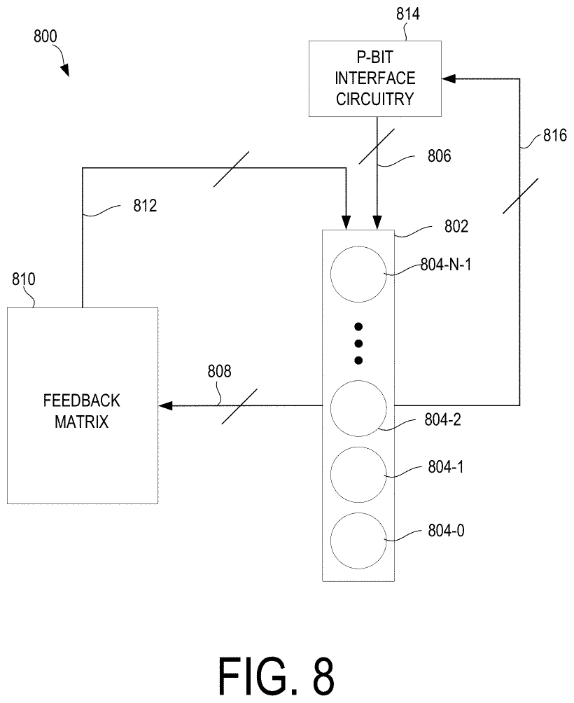

Referring now to FIG. 8, in one embodiment, a system 800 includes an array 802 of N probabilistic bits (or p-bit) 804, labeled p-bit 804-0, p-bit 804-1, p-bit 804-2, etc. As described in more detail below, the N p-bits 804 generate a digital random number that has a Gaussian distribution.

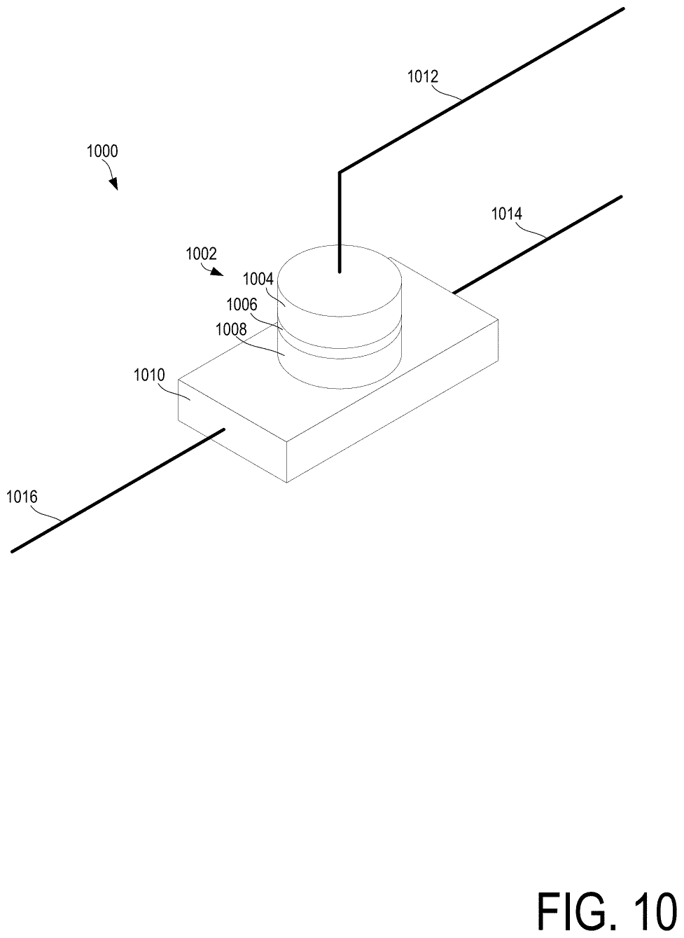

Each p-bit 804 is a digital bit that can take a value of either one or zero, and the value of each p-bit 804 fluctuates randomly. Each p-bit 804 has a bias input that can bias the p-bit 804 to preferentially be a one or a zero. A description of a p-bit 804 is described in more detail below in regard to FIGS. 10-13.

In the system 800, each p-bit 804 of the array 802 has a bias applied through N-bit bus 806 from p-bit interface circuitry 814. The p-bit interface circuitry 814 implements a bias vector represented by the vector h. The output of the p-bit array 802 is fed to a feedback matrix 810 through an N-bit bus 808. The feedback matrix 810 determines a bias to apply to each p-bit 804 based on the value of the other p-bits 804. The feedback matrix 810 implements a symmetric connection matrix J, where Jᵢⱼ=Jⱼᵢ represents the strength of the connection between the i^{th} and the j^{th} p-bit 804. In this case, an energy can be associated with the p-bit array 802 given by the following expression:

E=+−(ΣᵢΣⱼJᵢⱼsᵢsⱼ+Σᵢhᵢsᵢ), (3)

where sᵢ is the output of the i^{th} p-bit 804 written in bipolar notation (i.e., with possible values of ±1). The equation for E can be rewritten in a more compact matrix notation:

E=−({s}^{T}[J]{s}+{h}^{T}{s}). (4)

The p-bit array 802 can fluctuates through any of the possible 2^{N} states and follows the Boltzmann distribution:

$$p ( E ) = \frac{1}{Z} {e}^{- β E} . \qquad ( 5 )$$

where p(E) represents the probability that the p-bit array 802 is in a state with energy E, β is the pseudo inverse temperature, and Z is the partition function to normalize the probability function.

The digital output, bᵢ=0.5*(sᵢ+1), of the N p-bits 804 represent the N bits of the generated binary number n, which can be expressed as

n={d}^{T}{b}, (6)

where dᵢ=2^{N-i}. Substituting {b} with {s} leads to:

n=½{d}^{T}{s}+½n₀, (7)

or, equivalently:

n=½{s}^{T}{d}+½n₀, (8)

where n₀=2^{N}−1. Multiplying Eqs. (7) and (8) together gives:

$${n}^{2} - \frac{{n}_{0}^{2}}{4} = \frac{1}{4} {\{ s \}}^{T} [ D ] \{ s \} + \frac{{n}_{0}}{2} {\{ d \}}^{T} \{ s \} , \qquad ( 9 )$$

where D={d}{d}^{T}.

Noting the similarity of the right sides of Eqs. (4) and (9), appropriate values for J and h can be derived that result in the two equations being equal. In particular, the values for J are determined by:

Jᵢⱼ=−2^{-i-j} (10)

and the values for h are determined by

hᵢ=−2⁻ⁱ⁺¹×(1−2^{-N}). (11)

With those values of J and h, the left half of Eq. (9) can be substituted for the energy in Eq. (5), resulting in a distribution of n that follows a Gaussian distribution:

$$p ( n ) = \frac{1}{Z} exp ( - β ( {n}^{2} - \frac{{n}_{0}^{2}}{4} ) ) . \qquad ( 12 )$$

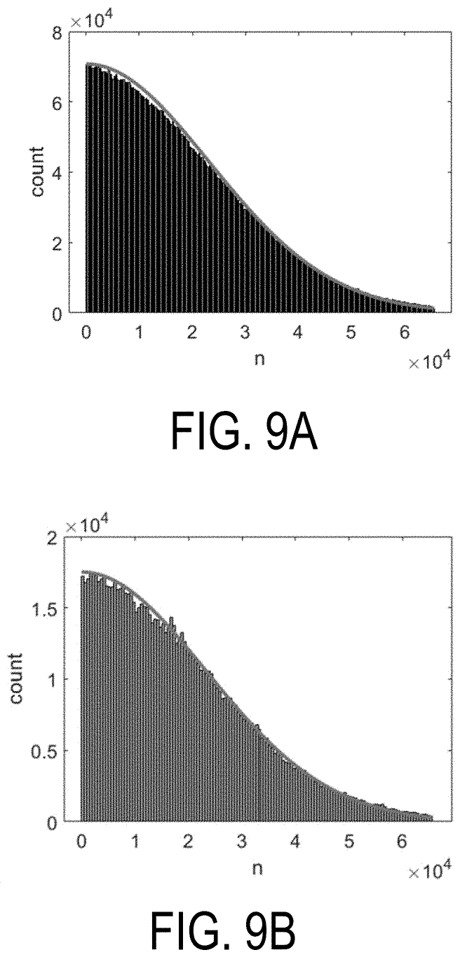

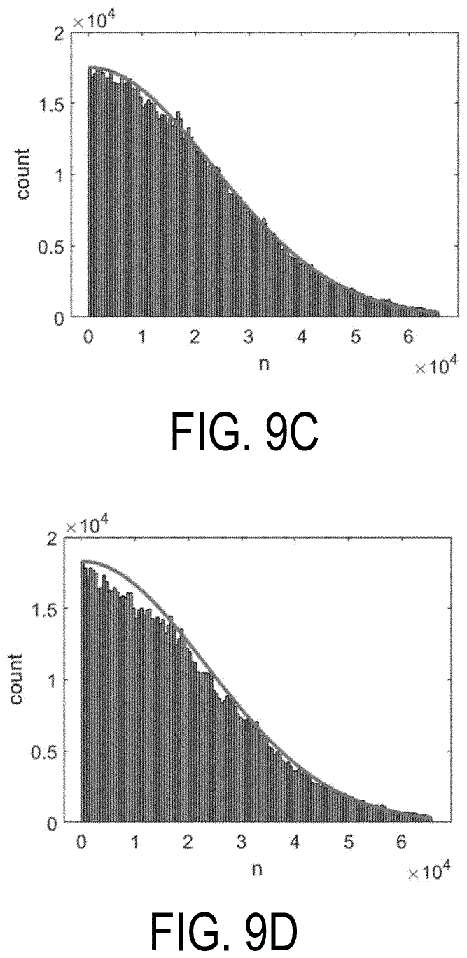

FIG. 9A shows the distribution of the generated random numbers n in one simulation of a p-bit array 802 with 16 p-bits 804. The generated numbers closely follow the theoretical Gaussian distribution shown with the solid line.

The J matrix and h vector given by Eqs. (10) and (11) require a precision of 2N bit for an exact implementation. However, J and h can be implemented using fewer bits, allowing for a simpler implementation with a relatively small deviation from a Gaussian distribution. For example, if J and h are implemented with 16 bits instead of 32, a distribution as shown in FIG. 9B results. If J and H are implemented with 8 or 6 bits, a distribution as shown in FIGS. 9C and 9D, respectively, result.

The mean (μ) and standard deviation (σ) of the generated Gaussian distribution can be set by modifying the interconnection matrix J and the bias vector h, such that Eqs. (10 and (11) are modified to read:

$${J}_{ij} = \frac{1}{2 {σ}^{2}} \times {J}_{ij}^{0} , \qquad ( 13 )$$

$${h}_{i} = \frac{( 1 - ( 2 μ / {n}_{0} ) )}{2 {σ}^{2}} \times {h}_{i}^{0} , \qquad ( 14 )$$

where Jᵢⱼ⁰ and hᵢ⁰ are the original expressions for the interconnection and bias values given in Eqs. (10) and (11).

It should be appreciated that a Gaussian distribution is merely one possible distribution that the p-bit array 802 can generate for particular values of J and h. Different values of J and H may be used, depending on the desired distribution.

In the illustrative embodiment, the p-bits 804 are implemented using an MTJ, as discussed in more detail below in regard to FIGS. 10-13. In other embodiments, other p-bit arrays may be used.

The feedback matrix 810 and/or bias vector h may be implemented in any suitable manner. For example, in one embodiment, the feedback matrix 810 and/or bias vector h may include an array of resistors that apply a particular bias current to a p-bit based on a voltage applied to the resistor, which in turn depends on the state of the p-bit array 802. In some embodiments, the feedback matrix 810 and/or bias vector h may be fixed at the time of manufacture and may not be changed. In other embodiments, the feedback matrix 810 and/or bias vector h may be programmable.

The p-bit interface circuitry 814 is configured to interface with the p-bit array 802 and other components of the system 800. The p-bit interface circuitry 814 may be integrated with the p-bit array 802 and other components of the system 800 on the same chip, on a multi-chip package, on a system-on-a-chip, on a separate chip or package, etc. The p-bit interface circuitry 814 may include voltage and/or current sources, analog-to-digital converters, digital-to-analog converters, etc. The p-bit interface circuitry 814 and/or any other components of the system 800 may be integrated with or otherwise form part of a processor, an application-specific integrated circuit (ASIC), a field-programmable gate array (FPGA), a graphics processing unit (GPU), etc.

In the illustrative embodiment, the state of the p-bit array 802 randomly changes on a nanosecond timescale. For example, the state of the p-bit array 802 may change every, e.g., 1-10 nanoseconds. In use, the values of some or all of the p-bits 804 may be used to generate digital random numbers up to N bits. The digital random numbers may have a Gaussian distribution. The p-bits 804 may be used to generate random numbers in any suitable application, such as machine learning, Bayesian inference, optimization algorithms, simulations, etc. Like the MTJ 102, the randomness of p-bits 804 is thermally-driven and not deterministic, and so the p-bits 804 can act as a true random number generator (as opposed to a deterministic pseudo-random number generator).

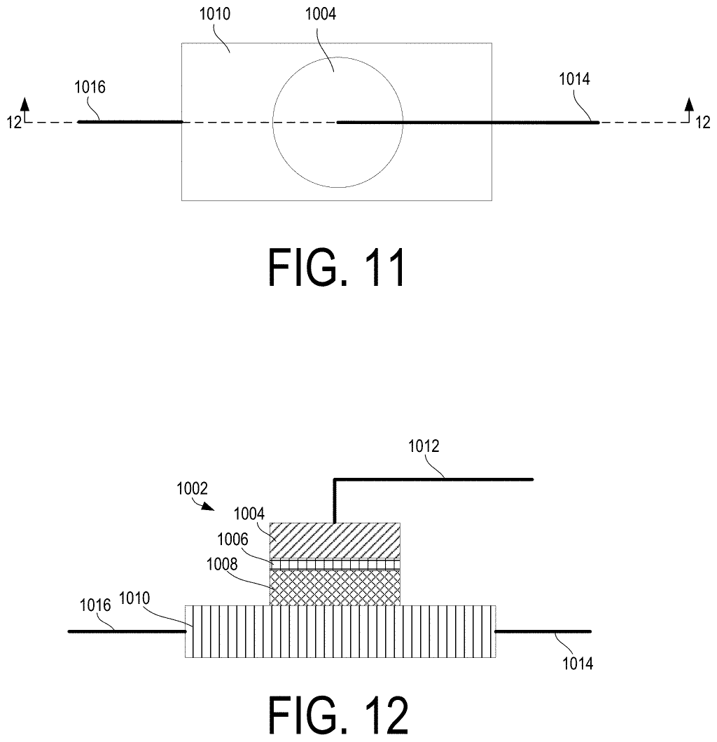

Referring now to FIG. 10, in one embodiment, a system 1000 that forms a portion of a p-bit 802 includes an MTJ 1002, which includes a reference ferromagnetic layer 1004, a dielectric layer 1006, and a free ferromagnetic layer 1008. FIG. 11 shows a top-down view of the system 1000, and FIG. 12 shows a cross-sectional view of the system 1000. The system 1000 also includes an SOT layer 1010 that can apply a controllable bias to the MTJ 1002 as well as electrodes 1012, 1014, and 1016. Electrode 1012 allows the resistance of the MTJ 1002 to be probed, electrode 1014 provides a ground for electrodes 1012 and 1016, and electrode 1016 allows current to be provided to the SOT layer 1010. The MTJ 1002, the SOT layer 1010, and the electrodes 1012, 1014, 1016 may be similar or identical to the corresponding component of the system 100 described above, a description of which will not be repeated in the interest of clarity.

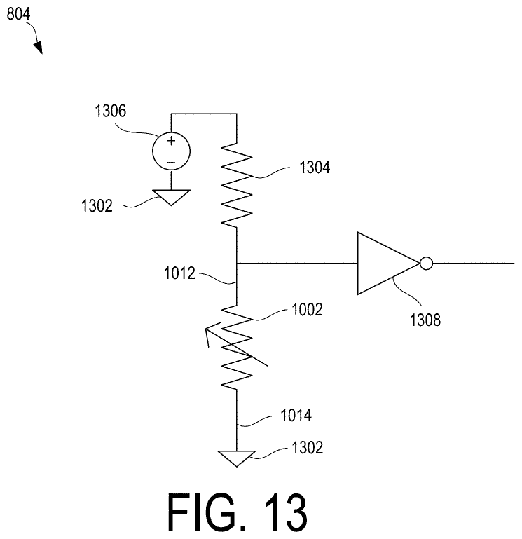

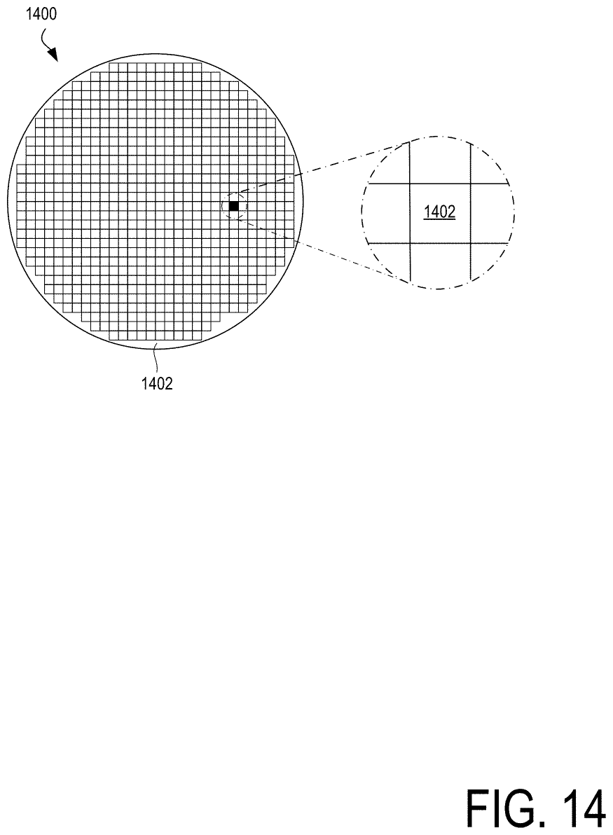

Referring now to FIG. 13, in one embodiment, a p-bit 804 may be implemented with the MTJ 1002. The MTJ 1002 is connected with another resistor 1304 to create a voltage divider. A voltage source 1306 is connected to the second resistor 1304 and to ground 1302, as shown in FIG. 13, and the MTJ 1002 is connected to ground 1302 as well.

A logic gate 1308 is connected between the MTJ 1002 and the second resistor 1304. The logic gate 1308 has a threshold voltage, and a voltage below that threshold will act as a logical “0” input, and a voltage above that threshold will act as a logical “1” input. The MTJ 1002 has a threshold resistance corresponding to the threshold voltage of the logic gate 1308. When the MTJ 1002 has a resistance below a threshold, the voltage at the logic gate 1308 acts as a logical “0” input to the logic gate 1308. When the MTJ 1002 has a resistance above a threshold, the voltage at the logic gate 1308 acts as a logical “1” input to the logic gate 1308. As the resistance of the MTJ 1002 will fluctuate randomly, the output of the logic gate 1308 will also fluctuate randomly. The likelihood that the MTJ 1002 has a resistance above the threshold value can be controlled based on the current in the SOT layer 1010. The logic gate 1308 may be any suitable logic gate, such as a buffer or not gate. The logic gate 1308 may be clocked or unclocked.

It should be appreciated that the p-bit 804 shown in FIG. 13 is merely one possible embodiment of a p-bit and that other types of p-bits may be used as well.

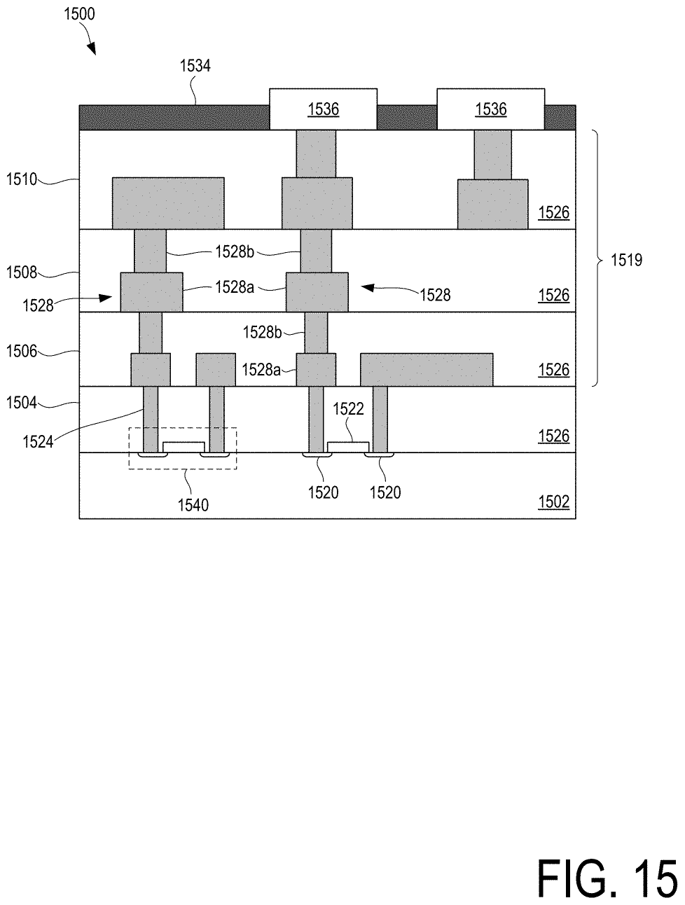

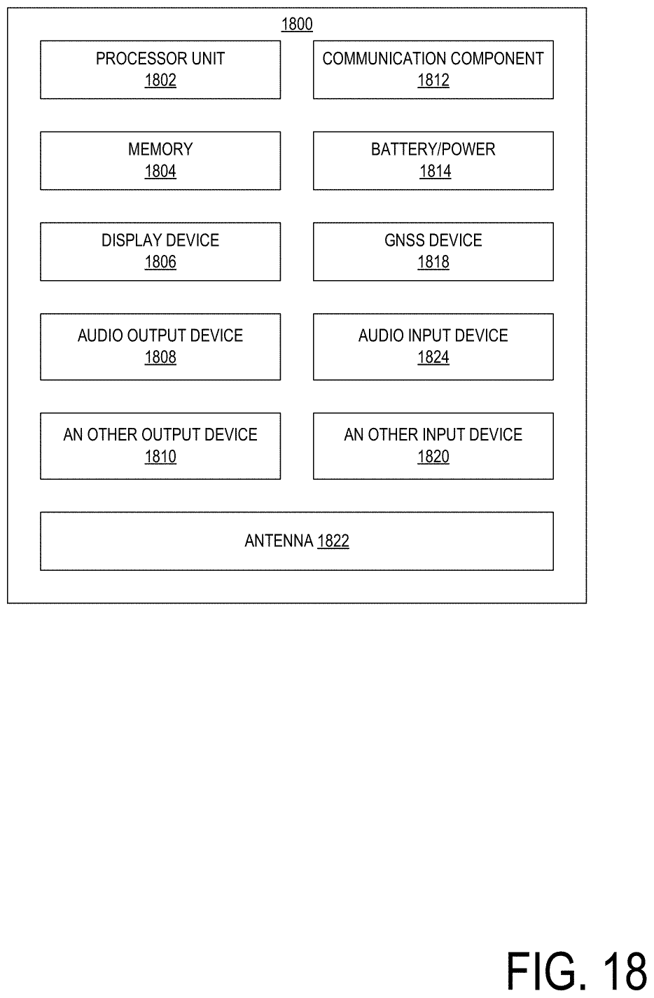

FIG. 14 is a top view of a wafer 1400 and dies 1402 that may include any of the MTJs 102, 1002 and related circuitry disclosed herein. The wafer 1400 may be composed of semiconductor material and may include one or more dies 1402 having integrated circuit structures formed on a surface of the wafer 1400. The individual dies 1402 may be a repeating unit of an integrated circuit product that includes any suitable integrated circuit. After the fabrication of the semiconductor product is complete, the wafer 1400 may undergo a singulation process in which the dies 1402 are separated from one another to provide discrete “chips” of the integrated circuit product. The die 1402 may include one or more transistors (e.g., some of the transistors 1540 of FIG. 15, discussed below), supporting circuitry to route electrical signals to the transistors, passive components (e.g., signal traces, resistors, capacitors, or inductors), and/or any other integrated circuit components. In some embodiments, the wafer 1400 or the die 1402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1402. For example, a memory array formed by multiple memory devices may be formed on a same die 1402 as a processor unit (e.g., the processor unit 1802 of FIG. 18) or other logic that is configured to store information in the memory devices or execute instructions stored in the memory array. Various ones of the systems 100, 800 disclosed herein may be manufactured using a die-to-wafer assembly technique in which some dies are attached to a wafer 1400 that include others of the dies, and the wafer 1400 is subsequently singulated.

FIG. 15 is a cross-sectional side view of an integrated circuit device 1500 that may include any of the MTJs 102, 1002 disclosed herein. One or more of the integrated circuit devices 1500 may be included in one or more dies 1402 (FIG. 14). The integrated circuit device 1500 may be formed on a die substrate 1502 (e.g., the wafer 1400 of FIG. 14) and may be included in a die (e.g., the die 1402 of FIG. 14). The die substrate 1502 may be a semiconductor substrate composed of semiconductor material systems including, for example, n-type or p-type materials systems (or a combination of both). The die substrate 1502 may include, for example, a crystalline substrate formed using a bulk silicon or a silicon-on-insulator (SOI) substructure. In some embodiments, the die substrate 1502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an integrated circuit device 1500 may be used. The die substrate 1502 may be part of a singulated die (e.g., the dies 1402 of FIG. 14) or a wafer (e.g., the wafer 1400 of FIG. 14).

The integrated circuit device 1500 may include one or more device layers 1504 disposed on the die substrate 1502. The device layer 1504 may include features of one or more transistors 1540 (e.g., metal oxide semiconductor field-effect transistors (MOSFETs)) formed on the die substrate 1502. The transistors 1540 may include, for example, one or more source and/or drain (S/D) regions 1520, a gate 1522 to control current flow between the S/D regions 1520, and one or more S/D contacts 1524 to route electrical signals to/from the S/D regions 1520. The transistors 1540 may include additional features not depicted for the sake of clarity, such as device isolation regions, gate contacts, and the like. The transistors 1540 are not limited to the type and configuration depicted in FIG. 15 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

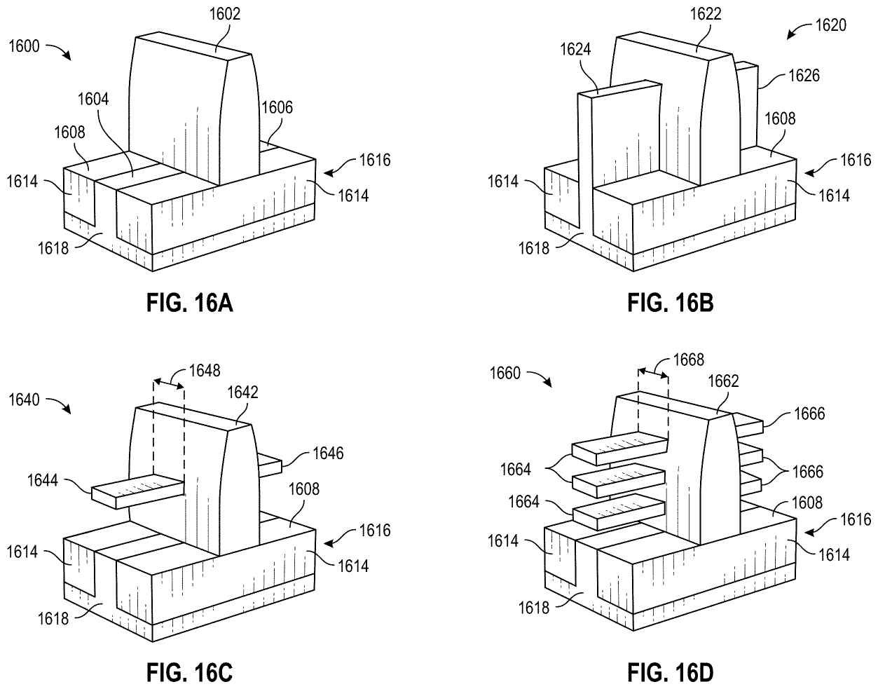

FIGS. 16A-16D are simplified perspective views of example planar, FinFET, gate-all-around, and stacked gate-all-around transistors. The transistors illustrated in FIGS. 16A-16D are formed on a substrate 1616 having a surface 1608. Isolation regions 1614 separate the source and drain regions of the transistors from other transistors and from a bulk region 1618 of the substrate 1616.

FIG. 16A is a perspective view of an example planar transistor 1600 comprising a gate 1602 that controls current flow between a source region 1604 and a drain region 1606. The transistor 1600 is planar in that the source region 1604 and the drain region 1606 are planar with respect to the substrate surface 1608.

FIG. 16B is a perspective view of an example FinFET transistor 1620 comprising a gate 1622 that controls current flow between a source region 1624 and a drain region 1626. The transistor 1620 is non-planar in that the source region 1624 and the drain region 1626 comprise “fins” that extend upwards from the substrate surface 1628. As the gate 1622 encompasses three sides of the semiconductor fin that extends from the source region 1624 to the drain region 1626, the transistor 1620 can be considered a tri-gate transistor. FIG. 16B illustrates one S/D fin extending through the gate 1622, but multiple S/D fins can extend through the gate of a FinFET transistor.

FIG. 16C is a perspective view of a gate-all-around (GAA) transistor 1640 comprising a gate 1642 that controls current flow between a source region 1644 and a drain region 1646. The transistor 1640 is non-planar in that the source region 1644 and the drain region 1646 are elevated from the substrate surface 1628.

FIG. 16D is a perspective view of a GAA transistor 1660 comprising a gate 1662 that controls current flow between multiple elevated source regions 1664 and multiple elevated drain regions 1666. The transistor 1660 is a stacked GAA transistor as the gate controls the flow of current between multiple elevated S/D regions stacked on top of each other. The transistors 1640 and 1660 are considered gate-all-around transistors as the gates encompass all sides of the semiconductor portions that extends from the source regions to the drain regions. The transistors 1640 and 1660 can alternatively be referred to as nanowire, nanosheet, or nanoribbon transistors depending on the width (e.g., widths 1648 and 1668 of transistors 1640 and 1660, respectively) of the semiconductor portions extending through the gate.

Returning to FIG. 15, a transistor 1540 may include a gate 1522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1540 along the source-channel-drain direction, the gate electrode may consist of a U-shaped structure that includes a bottom portion substantially parallel to the surface of the die substrate 1502 and two sidewall portions that are substantially perpendicular to the top surface of the die substrate 1502. In other embodiments, at least one of the metal layers that form the gate electrode may simply be a planar layer that is substantially parallel to the top surface of the die substrate 1502 and does not include sidewall portions substantially perpendicular to the top surface of the die substrate 1502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of individual transistors 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes them to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1520 may be formed using one or more alternate semiconductor materials such as germanium or a group III-V material or alloy. In further embodiments, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with the interconnect structures 1528 of the interconnect layers 1506-1510. The one or more interconnect layers 1506-1510 may form a metallization stack (also referred to as an “ILD stack”) 1519 of the integrated circuit device 1500.

The interconnect structures 1528 may be arranged within the interconnect layers 1506-1510 to route electrical signals according to a wide variety of designs; in particular, the arrangement is not limited to the particular configuration of interconnect structures 1528 depicted in FIG. 15. Although a particular number of interconnect layers 1506-1510 is depicted in FIG. 15, embodiments of the present disclosure include integrated circuit devices having more or fewer interconnect layers than depicted.

In some embodiments, the interconnect structures 1528 may include lines 1528a and/or vias 1528b filled with an electrically conductive material such as a metal. The lines 1528a may be arranged to route electrical signals in a direction of a plane that is substantially parallel with a surface of the die substrate 1502 upon which the device layer 1504 is formed. For example, the lines 1528a may route electrical signals in a direction in and out of the page and/or in a direction across the page from the perspective of FIGS. 3 and/or 12. The vias 1528b may be arranged to route electrical signals in a direction of a plane that is substantially perpendicular to the surface of the die substrate 1502 upon which the device layer 1504 is formed. In some embodiments, the vias 1528b may electrically couple lines 1528a of different interconnect layers 1506-1510 together.

The interconnect layers 1506-1510 may include a dielectric material 1526 disposed between the interconnect structures 1528, as shown in FIG. 15. In some embodiments, dielectric material 1526 disposed between the interconnect structures 1528 in different ones of the interconnect layers 1506-1510 may have different compositions; in other embodiments, the composition of the dielectric material 1526 between different interconnect layers 1506-1510 may be the same. The device layer 1504 may include a dielectric material 1526 disposed between the transistors 1540 and a bottom layer of the metallization stack as well. The dielectric material 1526 included in the device layer 1504 may have a different composition than the dielectric material 1526 included in the interconnect layers 1506-1510; in other embodiments, the composition of the dielectric material 1526 in the device layer 1504 may be the same as a dielectric material 1526 included in any one of the interconnect layers 1506-1510.

A first interconnect layer 1506 (referred to as Metal 1 or “M1”) may be formed directly on the device layer 1504. In some embodiments, the first interconnect layer 1506 may include lines 1528a and/or vias 1528b, as shown. The lines 1528a of the first interconnect layer 1506 may be coupled with contacts (e.g., the S/D contacts 1524) of the device layer 1504. The vias 1528b of the first interconnect layer 1506 may be coupled with the lines 1528a of a second interconnect layer 1508.

The second interconnect layer 1508 (referred to as Metal 2 or “M2”) may be formed directly on the first interconnect layer 1506. In some embodiments, the second interconnect layer 1508 may include via 1528b to couple the lines 1528 of the second interconnect layer 1508 with the lines 1528a of a third interconnect layer 1510. Although the lines 1528a and the vias 1528b are structurally delineated with a line within individual interconnect layers for the sake of clarity, the lines 1528a and the vias 1528b may be structurally and/or materially contiguous (e.g., simultaneously filled during a dual-damascene process) in some embodiments.

The third interconnect layer 1510 (referred to as Metal 3 or “M3”) (and additional interconnect layers, as desired) may be formed in succession on the second interconnect layer 1508 according to similar techniques and configurations described in connection with the second interconnect layer 1508 or the first interconnect layer 1506. In some embodiments, the interconnect layers that are “higher up” in the metallization stack 1519 in the integrated circuit device 1500 (i.e., farther away from the device layer 1504) may be thicker that the interconnect layers that are lower in the metallization stack 1519, with lines 1528a and vias 1528b in the higher interconnect layers being thicker than those in the lower interconnect layers.

The integrated circuit device 1500 may include a solder resist material 1534 (e.g., polyimide or similar material) and one or more conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to external devices. For example, solder bonds may be formed on the one or more conductive contacts 1536 to mechanically and/or electrically couple an integrated circuit die including the integrated circuit device 1500 with another component (e.g., a printed circuit board). The integrated circuit device 1500 may include additional or alternate structures to route the electrical signals from the interconnect layers 1506-1510; for example, the conductive contacts 1536 may include other analogous features (e.g., posts) that route the electrical signals to external components.

In some embodiments in which the integrated circuit device 1500 is a double-sided die, the integrated circuit device 1500 may include another metallization stack (not shown) on the opposite side of the device layer(s) 1504. This metallization stack may include multiple interconnect layers as discussed above with reference to the interconnect layers 1506-1510, to provide conductive pathways (e.g., including conductive lines and vias) between the device layer(s) 1504 and additional conductive contacts (not shown) on the opposite side of the integrated circuit device 1500 from the conductive contacts 1536.

In other embodiments in which the integrated circuit device 1500 is a double-sided die, the integrated circuit device 1500 may include one or more through silicon vias (TSVs) through the die substrate 1502; these TSVs may make contact with the device layer(s) 1504, and may provide conductive pathways between the device layer(s) 1504 and additional conductive contacts (not shown) on the opposite side of the integrated circuit device 1500 from the conductive contacts 1536. In some embodiments, TSVs extending through the substrate can be used for routing power and ground signals from conductive contacts on the opposite side of the integrated circuit device 1500 from the conductive contacts 1536 to the transistors 1540 and any other components integrated into the die 1500, and the metallization stack 1519 can be used to route I/O signals from the conductive contacts 1536 to transistors 1540 and any other components integrated into the die 1500.

Multiple integrated circuit devices 1500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

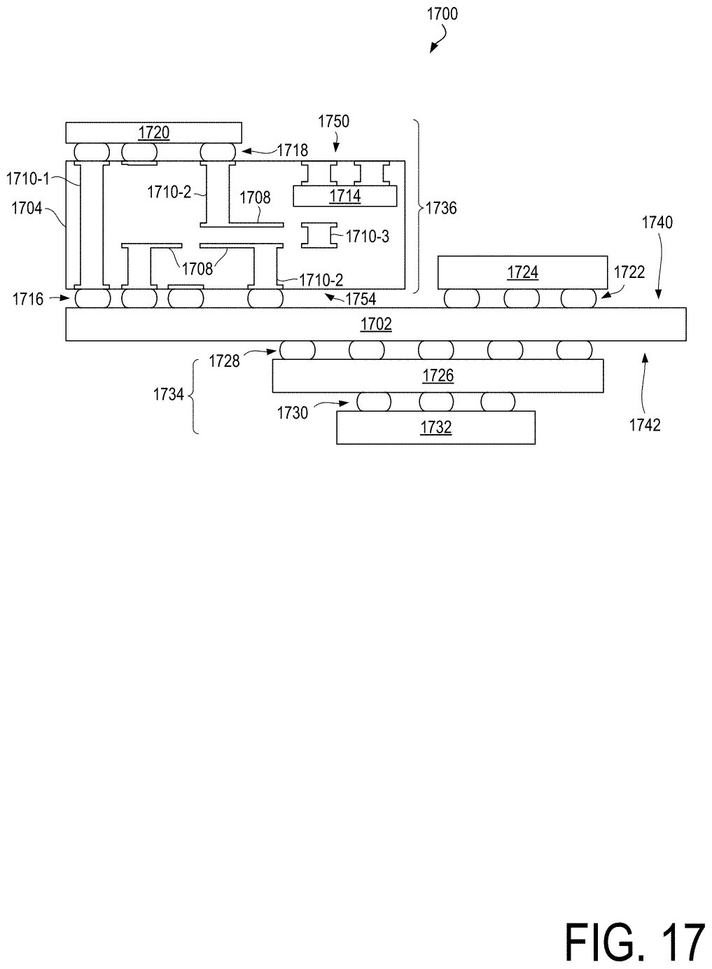

FIG. 17 is a cross-sectional side view of an integrated circuit device assembly 1700 that may include any of the MTJs 102, 1002 and related components disclosed herein. The integrated circuit device assembly 1700 includes a number of components disposed on a circuit board 1702 (which may be a motherboard, system board, mainboard, etc.). The integrated circuit device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. The integrated circuit device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 17), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1716 may serve as the coupling components illustrated or described for any of the substrate assembly or substrate assembly components described herein, as appropriate.

The package-on-interposer structure 1736 may include an integrated circuit component 1720 coupled to an interposer 1704 by coupling components 1718. The coupling components 1718 may take any suitable form for the application, such as the forms discussed above with reference to the coupling components 1716. Although a single integrated circuit component 1720 is shown in FIG. 17, multiple integrated circuit components may be coupled to the interposer 1704; indeed, additional interposers may be coupled to the interposer 1704. The interposer 1704 may provide an intervening substrate used to bridge the circuit board 1702 and the integrated circuit component 1720.

The integrated circuit component 1720 may be a packaged or unpacked integrated circuit product that includes one or more integrated circuit dies (e.g., the die 1402 of FIG. 14, the integrated circuit device 1500 of FIG. 15) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1720, a single monolithic integrated circuit die comprises solder bumps attached to contacts on the die. The solder bumps allow the die to be directly attached to the interposer 1704. The integrated circuit component 1720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1704 may spread connections to a wider pitch or reroute a connection to a different connection. For example, the interposer 1704 may couple the integrated circuit component 1720 to a set of ball grid array (BGA) conductive contacts of the coupling components 1716 for coupling to the circuit board 1702. In the embodiment illustrated in FIG. 17, the integrated circuit component 1720 and the circuit board 1702 are attached to opposing sides of the interposer 1704; in other embodiments, the integrated circuit component 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to through hole vias 1710-1 (that extend from a first face 1750 of the interposer 1704 to a second face 1754 of the interposer 1704), blind vias 1710-2 (that extend from the first or second faces 1750 or 1754 of the interposer 1704 to an internal metal layer), and buried vias 1710-3 (that connect internal metal layers).

In some embodiments, the interposer 1704 can comprise a silicon interposer. Through silicon vias (TSV) extending through the silicon interposer can connect connections on a first face of a silicon interposer to an opposing second face of the silicon interposer. In some embodiments, an interposer 1704 comprising a silicon interposer can further comprise one or more routing layers to route connections on a first face of the interposer 1704 to an opposing second face of the interposer 1704.

The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art. In embodiments where the interposer is a non-printed circuit board

The integrated circuit device assembly 1700 may include an integrated circuit component 1724 coupled to the first face 1740 of the circuit board 1702 by coupling components 1722. The coupling components 1722 may take the form of any of the embodiments discussed above with reference to the coupling components 1716, and the integrated circuit component 1724 may take the form of any of the embodiments discussed above with reference to the integrated circuit component 1720.

The integrated circuit device assembly 1700 illustrated in FIG. 17 includes a package-on-package structure 1734 coupled to the second face 1742 of the circuit board 1702 by coupling components 1728. The package-on-package structure 1734 may include an integrated circuit component 1726 and an integrated circuit component 1732 coupled together by coupling components 1730 such that the integrated circuit component 1726 is disposed between the circuit board 1702 and the integrated circuit component 1732. The coupling components 1728 and 1730 may take the form of any of the embodiments of the coupling components 1716 discussed above, and the integrated circuit components 1726 and 1732 may take the form of any of the embodiments of the integrated circuit component 1720 discussed above. The package-on-package structure 1734 may be configured in accordance with any of the package-on-package structures known in the art.

FIG. 18 is a block diagram of an example electrical device 1800 that may include one or more of the MTJs 102, 1002 and related components disclosed herein. For example, any suitable ones of the components of the electrical device 1800 may include one or more of the integrated circuit device assemblies 1700, integrated circuit components 1720, integrated circuit devices 1500, or integrated circuit dies 1402 disclosed herein. A number of components are illustrated in FIG. 18 as included in the electrical device 1800, but any one or more of these components may be omitted or duplicated, as suitable for the application. In some embodiments, some or all of the components included in the electrical device 1800 may be attached to one or more motherboards mainboards, or system boards. In some embodiments, one or more of these components are fabricated onto a single system-on-a-chip (SoC) die.

Additionally, in various embodiments, the electrical device 1800 may not include one or more of the components illustrated in FIG. 18, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include one or more processor units 1802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1800 may include a memory 1804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1804 may include memory that is located on the same integrated circuit die as the processor unit 1802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1800 can comprise one or more processor units 1802 that are heterogeneous or asymmetric to another processor unit 1802 in the electrical device 1800. There can be a variety of differences between the processing units 1802 in a system in terms of a spectrum of metrics of merit including architectural, microarchitectural, thermal, power consumption characteristics, and the like. These differences can effectively manifest themselves as asymmetry and heterogeneity among the processor units 1802 in the electrical device 1800.

In some embodiments, the electrical device 1800 may include a communication component 1812 (e.g., one or more communication components). For example, the communication component 1812 can manage wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication component 1812 may manage wired communications, such as electrical, optical, or any other suitable communication protocols (e.g., IEEE 802.3 Ethernet standards). As noted above, the communication component 1812 may include multiple communication components. For instance, a first communication component 1812 may be dedicated to shorter-range wireless communications such as Wi-Fi or Bluetooth, and a second communication component 1812 may be dedicated to longer-range wireless communications such as global positioning system (GPS), EDGE, GPRS, CDMA, WiMAX, LTE, EV-DO, or others. In some embodiments, a first communication component 1812 may be dedicated to wireless communications, and a second communication component 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any embedded or wired or wirelessly connected external device that generates an audible indicator, such speakers, headsets, or earbuds.

The electrical device 1800 may include an audio input device 1824 (or corresponding interface circuitry, as discussed above). The audio input device 1824 may include any embedded or wired or wirelessly connected device that generates a signal representative of a sound, such as microphones, microphone arrays, or digital instruments (e.g., instruments having a musical instrument digital interface (MIDI) output). The electrical device 1800 may include a Global Navigation Satellite System (GNSS) device 1818 (or corresponding interface circuitry, as discussed above), such as a Global Positioning System (GPS) device. The GNSS device 1818 may be in communication with a satellite-based system and may determine a geolocation of the electrical device 1800 based on information received from one or more GNSS satellites, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1800 may be any other electronic device that processes data. In some embodiments, the electrical device 1800 may comprise multiple discrete physical components. Given the range of devices that the electrical device 1800 can be manifested as in various embodiments, in some embodiments, the electrical device 1800 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a magnetic tunnel junction; a piezoelectric layer mechanically coupled to the magnetic tunnel junction; and a spin orbit torque layer between the magnetic tunnel junction and the piezoelectric layer.

Example 2 includes the subject matter of Example 1, and further including circuitry to use a resistance of the magnetic tunnel junction as a source of non-uniform random values.

Example 3 includes the subject matter of any of Examples 1 and 2, and further including an analog-to-digital converter to measure a resistance of the magnetic tunnel junction to generate a digital random number.

Example 4 includes the subject matter of any of Examples 1-3, and further including a normal metal layer between the magnetic tunnel junction and the spin orbit torque layer; and an isolation layer between the normal metal layer and the spin orbit torque layer.

Example 5 includes the subject matter of any of Examples 1-4, and wherein the isolation layer comprises nickel and oxygen.

Example 6 includes the subject matter of any of Examples 1-5, and wherein the spin orbit torque layer is a heavy metal, an antiferromagnet, a topological insulator, or a transition metal dichalcogenides.

Example 7 includes the subject matter of any of Examples 1-6, and wherein a resistance of the magnetic tunnel junction fluctuates at a timescale of less than 10 nanoseconds.

Example 8 includes the subject matter of any of Examples 1-7, and wherein a distribution of a resistance of the magnetic tunnel junction is Gaussian.

Example 9 includes the subject matter of any of Examples 1-8, and wherein the magnetic tunnel junction comprises a first ferromagnetic layer, a dielectric layer, and a second ferromagnetic layer, wherein the dielectric layer is between the first ferromagnetic layer and the second ferromagnetic layer, wherein the second ferromagnetic layer is a free nanomagnet.

Example 10 includes the subject matter of any of Examples 1-9, and wherein the first ferromagnetic layer comprises iron, wherein the second ferromagnetic layer comprises iron, wherein the dielectric layer comprises magnesium and oxygen.

Example 11 includes an integrated circuit component comprising the apparatus of claim 1.

Example 12 includes a system comprising the integrated circuit component of claim 11 and one or more memory devices.

Example 13 includes an apparatus comprising a plurality of a probabilistic bits (p-bits), wherein individual p-bits of the plurality of p-bits have an input that controls a bias of an output of the corresponding p-bit; and a feedback matrix to accept an input from the output of individual p-bits of the plurality of p-bits and provide an output to the input of individual p-bits of the plurality of p-bits, wherein the input of individual p-bits of the plurality of p-bits depends on the output of other p-bits of the plurality of p-bits.

Example 14 includes the subject matter of Example 13, and wherein the plurality of p-bits represent an n-bit number, further comprising circuitry to use n-bit number as a source of non-uniform random numbers.

Example 15 includes the subject matter of any of Examples 13 and 14, and wherein the plurality of p-bits represent an n-bit number, wherein the n-bit number has a Gaussian distribution.

Example 16 includes the subject matter of any of Examples 13-15, and further including p-bit interface circuitry connected to the input of individual p-bits of the plurality of p-bits to provide a bias to the corresponding p-bit, wherein the bias provided by the p-bit interface circuitry depends on the output of the corresponding p-bit.

Example 17 includes the subject matter of any of Examples 13-16, and wherein individual p-bits of the plurality of p-bits comprise a magnetic tunnel junction, wherein individual magnetic tunnel junctions of the plurality of p-bits comprise a first ferromagnetic layer, a dielectric layer, and a second ferromagnetic layer, and a bias input, wherein the dielectric layer of individual magnetic tunnel junctions of the plurality of p-bits is between the corresponding first ferromagnetic layer and the corresponding second ferromagnetic layer, wherein a magnetization direction of the second ferromagnetic layer of individual magnetic tunnel junctions of the plurality of p-bits randomly fluctuates, wherein a resistance of the magnetic tunnel junction of individual p-bits of the plurality of p-bits depends on the magnetization direction of the second ferromagnetic layer, wherein individual p-bits of the plurality of p-bits are to provide the corresponding output based on the resistance of the corresponding magnetic tunnel junction.

Example 18 includes the subject matter of any of Examples 13-17, and wherein individual p-bits of the plurality of p-bits comprise a spin-orbit torque layer, wherein, in response to an applied current, the spin-orbit torque layer of individual p-bits of the plurality of p-bits bias the output of the corresponding p-bit.

Example 19 includes the subject matter of any of Examples 13-18, and wherein the feedback matrix is a matrix J, wherein values of element Jij is −2−i−j for any value of i and j.

Example 20 includes the subject matter of any of Examples 13-19, and wherein the plurality of p-bits is n p-bits, wherein values of feedback matrix have a precision that is less than or equal to n bits.

Example 21 includes a integrated circuit component comprising the apparatus of claim 13.

Example 22 includes a system comprising the integrated circuit component of claim 21 and one or more memory devices.

Example 23 includes an apparatus comprising one or more magnetic tunnel junctions; and means for using the one or more magnetic tunnel junctions to generate non-uniform random numbers.

Example 24 includes the subject matter of Example 23, and further including a piezoelectric layer mechanically coupled to a magnetic tunnel junction of the one or more magnetic tunnel junctions, wherein, in response to an applied voltage, the piezoelectric layer is to apply a mechanical strain that affects a standard deviation of a distribution of a resistance of the magnetic tunnel junction.

Example 25 includes the subject matter of any of Examples 23 and 24, and wherein the means for using the one or more magnetic tunnel junctions to generate non-uniform random numbers comprises an analog-to-digital converter to measure the resistance of the magnetic tunnel junction.

Example 26 includes the subject matter of any of Examples 23-25, and wherein the one or more magnetic tunnel junctions comprises a plurality of magnetic tunnel junctions, further comprising a plurality of logic gates, wherein an output of individual logic gates of the plurality of logic gates depend on a resistance of a corresponding magnetic tunnel junction of the plurality of magnetic tunnel junctions.

1. An apparatus comprising:
a magnetic tunnel junction;
a piezoelectric layer mechanically coupled to the magnetic tunnel junction; and
a spin orbit torque layer between the magnetic tunnel junction and the piezoelectric layer.

2. The apparatus of claim 1, further comprising circuitry to use a resistance of the magnetic tunnel junction as a source of non-uniform random values.

3. The apparatus of claim 1, further comprising an analog-to-digital converter to measure a resistance of the magnetic tunnel junction to generate a digital random number.

4. The apparatus of claim 1, further comprising:
a normal metal layer between the magnetic tunnel junction and the spin orbit torque layer; and
an isolation layer between the normal metal layer and the spin orbit torque layer.

5. The apparatus of claim 4, wherein the isolation layer comprises nickel and oxygen.

6. The apparatus of claim 1, wherein a resistance of the magnetic tunnel junction fluctuates at a timescale of less than 10 nanoseconds.

7. The apparatus of claim 1, wherein a distribution of a resistance of the magnetic tunnel junction is Gaussian.

8. The apparatus of claim 1, wherein the magnetic tunnel junction comprises a first ferromagnetic layer, a dielectric layer, and a second ferromagnetic layer,
wherein the dielectric layer is between the first ferromagnetic layer and the second ferromagnetic layer,
wherein the second ferromagnetic layer is a free nanomagnet.

9. The apparatus of claim 8, wherein the first ferromagnetic layer comprises iron, wherein the second ferromagnetic layer comprises iron, wherein the dielectric layer comprises magnesium and oxygen.

10. An integrated circuit component comprising the apparatus of claim 1.

11. A system comprising the integrated circuit component of claim 10 and one or more memory devices.

12. An apparatus comprising:
a plurality of a probabilistic bits (p-bits), wherein individual p-bits of the plurality of p-bits have an input that controls a bias of an output of the corresponding p-bit; and
a feedback matrix to accept an input from the output of individual p-bits of the plurality of p-bits and provide an output to the input of individual p-bits of the plurality of p-bits, wherein the input of individual p-bits of the plurality of p-bits depends on the output of other p-bits of the plurality of p-bits.

13. The apparatus of claim 12, wherein the plurality of p-bits represent an n-bit number,
further comprising circuitry to use n-bit number as a source of non-uniform random numbers.

14. The apparatus of claim 12, wherein the plurality of p-bits represent an n-bit number, wherein the n-bit number has a Gaussian distribution.

15. The apparatus of claim 12, further comprising p-bit interface circuitry connected to the input of individual p-bits of the plurality of p-bits to provide a bias to the corresponding p-bit, wherein the bias provided by the p-bit interface circuitry depends on the output of the corresponding p-bit.

16. The apparatus of claim 12, wherein individual p-bits of the plurality of p-bits comprise a magnetic tunnel junction, wherein individual magnetic tunnel junctions of the plurality of p-bits comprise a first ferromagnetic layer, a dielectric layer, and a second ferromagnetic layer, and a bias input,
wherein the dielectric layer of individual magnetic tunnel junctions of the plurality of p-bits is between the corresponding first ferromagnetic layer and the corresponding second ferromagnetic layer,
wherein a magnetization direction of the second ferromagnetic layer of individual magnetic tunnel junctions of the plurality of p-bits randomly fluctuates,
wherein a resistance of the magnetic tunnel junction of individual p-bits of the plurality of p-bits depends on the magnetization direction of the second ferromagnetic layer,
wherein individual p-bits of the plurality of p-bits are to provide the corresponding output based on the resistance of the corresponding magnetic tunnel junction.

17. The apparatus of claim 15, wherein individual p-bits of the plurality of p-bits comprise a spin-orbit torque layer,
wherein, in response to an applied current, the spin-orbit torque layer of individual p-bits of the plurality of p-bits bias the output of the corresponding p-bit.

18. The apparatus of claim 12, wherein the feedback matrix is a matrix J, wherein values of element Jᵢⱼ is −2^{-i-j} for any value of i and j.

19. The apparatus of claim 12, wherein the plurality of p-bits is n p-bits, wherein values of feedback matrix have a precision that is less than or equal to n bits.

20. A integrated circuit component comprising the apparatus of claim 12.

21. A system comprising the integrated circuit component of claim 20 and one or more memory devices.

22. An apparatus comprising:
one or more magnetic tunnel junctions; and
means for using the one or more magnetic tunnel junctions to generate non-uniform random numbers.

23. The apparatus of claim 22,
further comprising a piezoelectric layer mechanically coupled to a magnetic tunnel junction of the one or more magnetic tunnel junctions, wherein, in response to an applied voltage, the piezoelectric layer is to apply a mechanical strain that affects a standard deviation of a distribution of a resistance of the magnetic tunnel junction.

24. The apparatus of claim 23, wherein the means for using the one or more magnetic tunnel junctions to generate non-uniform random numbers comprises an analog-to-digital converter to measure the resistance of the magnetic tunnel junction.

25. The apparatus of claim 22, wherein the one or more magnetic tunnel junctions comprises a plurality of magnetic tunnel junctions,
further comprising a plurality of logic gates, wherein an output of individual logic gates of the plurality of logic gates depend on a resistance of a corresponding magnetic tunnel junction of the plurality of magnetic tunnel junctions.
